(19) United States
(12) Patent Application Publication
(10) Pub. No.: US 2021/0304984 A1
(43) Pub. Date: Sep. 30, 2021

(54) KNOB TYPE WATERPROOF OPTICAL CONTROLLER WITH SNAP

(71) Applicant: Foshan Ojun Electrical Technology Co., Ltd., Foshan (CN)

(72) Inventors: Changxiong PAN, Foshan (CN); Yaoguang XIAO, Foshan (CN)

(73) Assignee: Foshan Ojun Electrical Technology Co., Ltd.

(21) Appl. No.: 17/037,852

(22) Filed: Sep. 30, 2020

(30) Foreign Application Priority Data
Mar. 28, 2020 (CN) 202020421306.5

(51) Int. Cl. H01H 19/06; H01H 19/32

(52) U.S. Cl. CPC H01H 19/06; H01H 19/32

(57) ABSTRACT

The disclosure discloses a knob type waterproof optical controller with a snap provided by the disclosure including a base and a cover, the base and the cover are threadedly connected to each other, and between the base and the cover, a snap structure for restricting relative rotation therebetween is provided, and with the snap structure, the base and the cover may be clamped and prevented from being retreated after being threadedly connected to each other, so as to prevent the optical controller structure from loosening during use, and the sealing gasket and the sealing retaining ring cooperate with each other, which may greatly improve the waterproof effect of the optical controller.

### CROSS-REFERENCE TO RELATED APPLICATIONS

This application claims priority to Chinese Patent Application No. 202020421306.5 with a filing date of Mar. 28, 2020. The content of the aforementioned applications, including any intervening amendments thereto, are incorporated herein by reference.

### TECHNICAL FIELD

The disclosure relates to the technical field of electronic processing, in particular to a knob type waterproof optical controller with a snap.

### BACKGROUND OF THE PRESENT INVENTION

The optical controller is an electronic device that controls on or off of a circuit through sensitive response of a photosensitive member to the light intensity, which is an automatic control device often used for power sources such as street lamps, lighting lamps, and advertising light boxes that need to be energized at night, and the optical controller in the prior art is prone to looseness in structure and the waterproof effect thereof is not good.

### SUMMARY OF PRESENT INVENTION

The object of the disclosure is to provide a knob type waterproof optical controller with a snap in order to solve the above problems, which has the advantages of avoiding loosening of the optical controller structure and good waterproof effect, please referring to the following description for details.

In order to achieve the above object, the disclosure provides the following technical solution.

A knob type waterproof optical controller with a snap provided by the disclosure includes a base and a cover, the base and the cover are threadedly connected to each other, and between the base and the cover, a snap structure for restricting relative rotation therebetween is provided.

Preferably, the snap structure includes an elastic snap strip, a notch and a snap groove, one end of the elastic snap strip is fixedly connected to the notch provided on an edge of an opening of the cover, the other end of the elastic snap strip protrudes from the edge of the opening of the cover, and the snap groove is formed on the base corresponding to the position of the notch.

Preferably, a lower end of the base is fixedly provided with an outer shoulder along its edge, an outer side of the base is provided with an outer thread, and an inner side of the opening end of the cover is provided with an inner thread, and the inner thread and the outer thread are threadedly connected to each other.

Preferably, a sealing retaining ring is fixedly disposed on an inner side wall of the cover, a sealing gasket is disposed on an outer edge of an upper end of the base, and the sealing gasket and the sealing retaining ring are sealingly connected with each other.

Preferably, three perforations are formed in the middle of the base for installing insertion posts and gaps between the insertion posts and the perforations are filled with waterproof sealing material.

Preferably, several anti-slip grooves evenly distributed are formed on an outer side of the cover.

Preferably, the sealing gasket is made of waterproof silicone material.

The beneficial effect is that with the snap structure, the base and the cover may be clamped and prevented from being retreated after being threadedly connected to each other, so as to prevent the optical controller structure from loosening during use, and the sealing gasket and the sealing retaining ring cooperate with each other, which may greatly improve the waterproof effect of the optical controller.

### DESCRIPTION OF THE DRAWINGS

In order to more clearly explain the technical solution in the embodiments of the disclosure or the prior art, the drawings that need to be used in the description of the embodiments or the prior art will be briefly introduced in the following, obviously, the drawings in the following description are just some embodiments of the disclosure, and to those of ordinary skill in the art, other drawings may be obtained based on these drawings without creative effort.

FIG. 1 is a front view of the disclosure;

FIG. 2 is a bottom view of FIG. 1 of the disclosure;

FIG. 3 is a perspective view of FIG. 1 of the disclosure;

FIG. 4 is a partial enlarged view of A of FIG. 1 of the disclosure;

FIG. 5 is a perspective view of a base of the disclosure;

FIG. 6 is a perspective view of the base of the disclosure from another direction;

FIG. 7 is a perspective view of a cover of the disclosure;

FIG. 8 is an assembly schematic diagram of the optical controller and a socket of the disclosure.

The reference signs are explained as follows: 1. Base; 1a. Outer shoulder; 1b. external thread; 2. Cover; 3. Anti-slip groove; 4. Snap structure; 4a. Elastic snap strip; 4b. Notch; 4c. Snap groove; 5. Perforation; 6. Insertion post; 7. Sealing gasket; 8. Inner thread; 9. Sealing retaining ring.

### DETAILED DESCRIPTION OF PREFERRED EMBODIMENTS

In order to make the object, technical solution and advantages of the disclosure clearer, the technical solution of the disclosure will be described in detail below. Obviously, the described embodiments are only a part of, rather than all the embodiments of the disclosure. Based on the embodiments of the disclosure, all other embodiments obtained by those of ordinary skill in the art without creative effort shall fall within the protection scope of the disclosure.

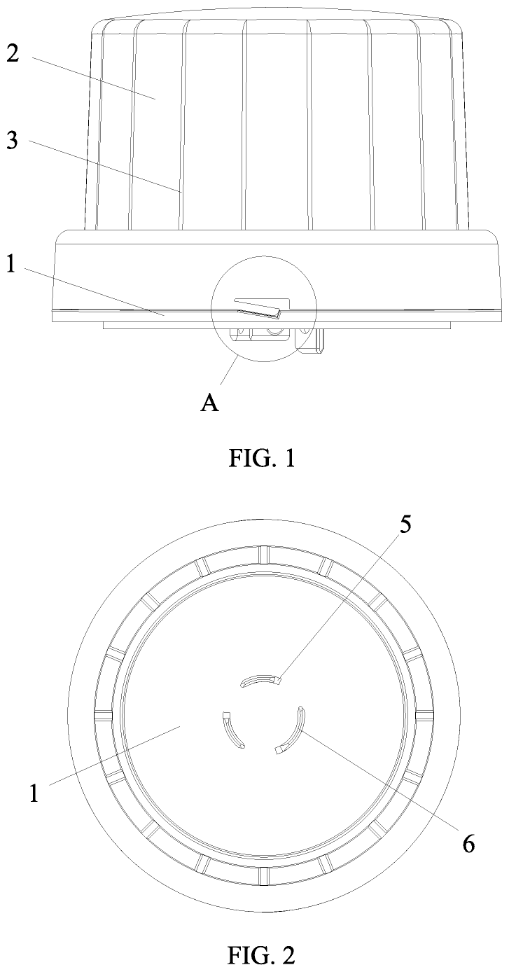

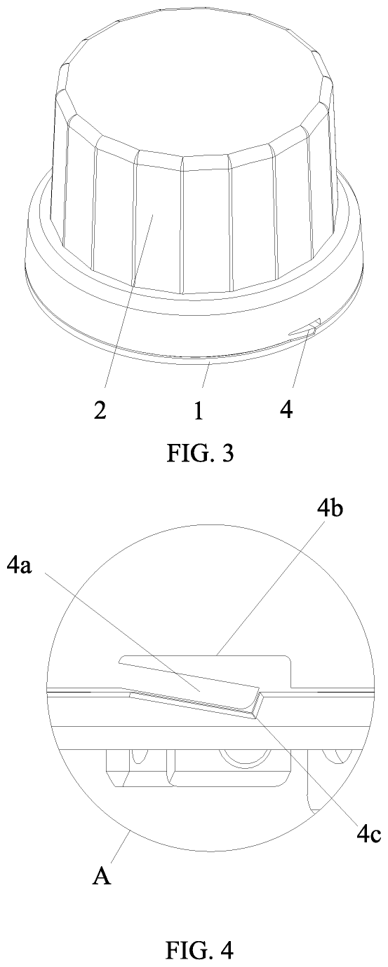

Referring to FIGS. 1 to 6, the disclosure provides a knob type waterproof optical controller with a snap, including a base 1 and a cover 2, the base 1 and the cover 2 are threadedly connected to each other, and between the base 1 and the cover 2, a snap structure 4 for restricting relative rotation therebetween is provided. After the base 1 and the cover 2 are threadedly connected to each other, the snap structure 4 may lock the position between the base 1 and the cover 2 to avoid twisting and loosening.

The snap structure 4 includes an elastic snap strip 4a, a notch 4b and a snap groove 4c, one end of the elastic snap strip 4a is fixedly connected to the notch 4b provided on an edge of an opening of the cover 2, the other end of the elastic snap strip 4a protrudes from the edge of the opening of the cover 2, and the snap groove 4c is formed on the base 1 corresponding to the position of the notch 4b.

A lower end of the base 1 is fixedly provided with an outer shoulder 1a along its edge, an outer side of the base 1 is provided with an outer thread 1b, and an inner side of the opening end of the cover 2 is provided with an inner thread 8, and the inner thread 8 and the outer thread 1b are threadedly connected to each other.

A sealing retaining ring 9 is fixedly disposed on an inner side wall of the cover 2, a sealing gasket 7 is disposed on an outer edge of an upper end of the base 1, and the sealing gasket 7 and the sealing retaining ring 9 are sealingly connected with each other. The sealing gasket 7 is made of waterproof silicone material.

Three perforations 5 are formed in the middle of the base 1 for installing insertion posts 6 and gaps between the insertion posts 6 and the perforations 5 are filled with waterproof sealing material, which may greatly improve the waterproof performance.

Several anti-slip grooves 3 evenly distributed are formed on an outer side of the cover 2. The cover 2 when held is prevented from sliding through the anti-slip grooves 3.

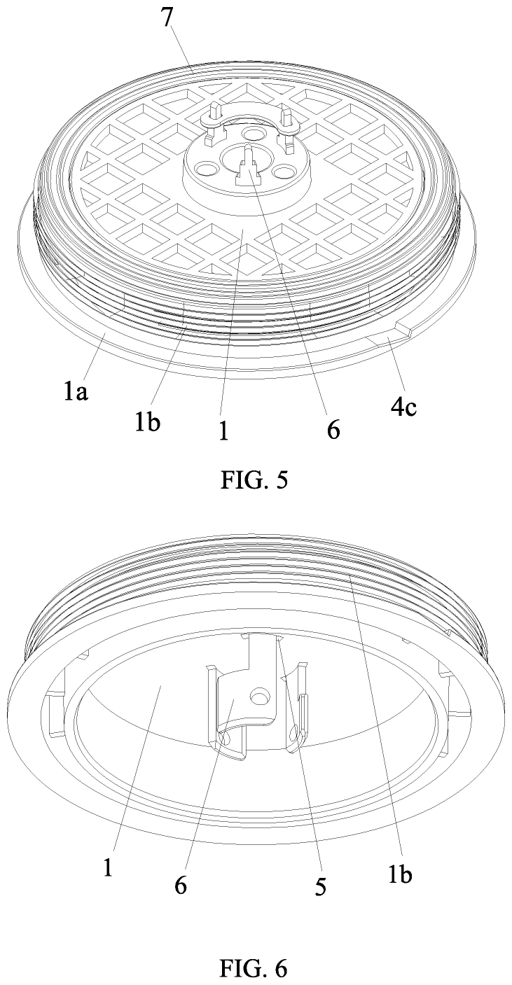

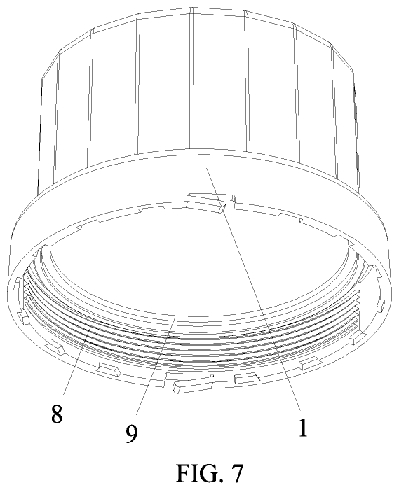

With the above structure, the base 1 and the cover 2 are threadedly connected to each other, the upper end of the base 1 with the outer thread 1b is inserted into the opening end of the cover 2, and the base 1 and the cover 2 threadedly rotate relative to each other. After the base 1 and the cover 2 are threadedly connected to each other, the elastic snap strip 4a snaps into the snap groove 4c formed in the corresponding position of the base 1, as shown in FIG. 5 of the specification, at which time, a movable end of the elastic snap strip 4a cooperates with the snap groove 4c to realize clamping of the base 1 and the cover 2 so that the base 1 and the cover 2 cannot rotate relative to each other, and at which time, the sealing gasket 7 on the outer edge of the upper end of the base 1 abuts the sealing retaining ring 9, and the sealing gasket 7 is in a compressed state to achieve waterproof sealing.

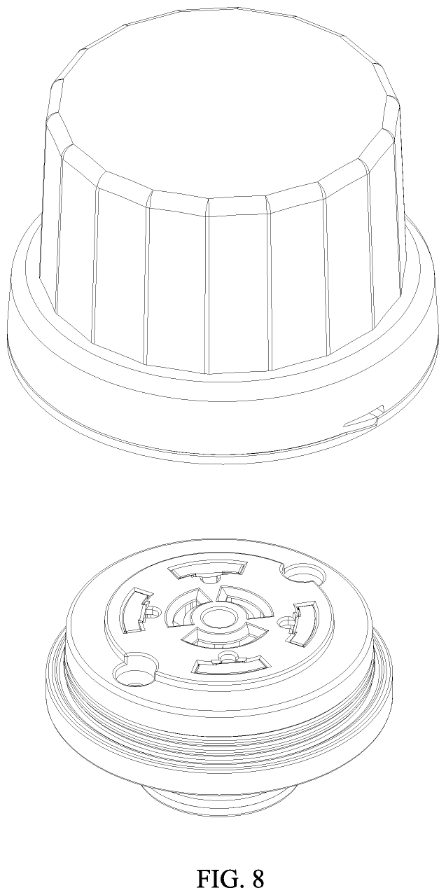

As shown in FIG. 8 of the specification, an upper part of the figure is the optical controller of the disclosure, and a lower part of the figure is a socket of the disclosure. When the cover 2 is held to threadedly connect the optical controller to the socket, the snap structure 4 may lock the position between the base 1 and the cover 2 to avoid twisting and loosening.

With the snap structure 4, the base 1 and the cover 2 may be clamped and prevented from being retreated after being threadedly connected to each other, so as to prevent the optical controller structure from loosening during use, and the sealing gasket 7 and the sealing retaining ring 9 cooperate with each other, which may greatly improve the waterproof effect of the optical controller.

The above are only specific embodiments of the disclosure, but the protection scope of the disclosure is not limited thereto, and any person skilled in the art may easily conceive change or replacement within the technical scope disclosed by the disclosure, which shall be covered within the protection scope of the disclosure. Therefore, the protection scope of the disclosure shall be based on the protection scope of the claims.

We claim:

1. A knob type waterproof optical controller with a snap, comprising a base (1) and a cover (2), wherein the base (1) and the cover (2) are threadedly connected to each other, and between the base (1) and the cover (2), a snap structure (4) for restricting relative rotation therebetween is provided.

2. The knob type waterproof optical controller with a snap of claim 1, wherein the snap structure (4) comprises an elastic snap strip (4a), a notch (4b) and a snap groove (4c), one end of the elastic snap strip (4a) is fixedly connected to the notch (4b) provided on an edge of an opening of the cover (2), the other end of the elastic snap strip (4a) protrudes from the edge of the opening of the cover (2), and the snap groove (4c) is formed on the base (1) corresponding to the position of the notch (4b).

3. The knob type waterproof optical controller with a snap of claim 1, wherein a lower end of the base (1) is fixedly provided with an outer shoulder (1a) along its edge, an outer side of the base (1) is provided with an outer thread (1b), and an inner side of the opening end of the cover (2) is provided with an inner thread (8), and the inner thread (8) and the outer thread (1b) are threadedly connected to each other.

4. The knob type waterproof optical controller with a snap of claim 1, wherein a sealing retaining ring (9) is fixedly disposed on an inner side wall of the cover (2), a sealing gasket (7) is disposed on an outer edge of an upper end of the base (1), and the sealing gasket (7) and the sealing retaining ring (9) are sealingly connected with each other.

5. The knob type waterproof optical controller with a snap of claim 1, wherein three perforations (5) are formed in the middle of the base (1) for installing insertion posts (6) and gaps between the insertion posts (6) and the perforations (5) are filled with waterproof sealing material.

6. The knob type waterproof optical controller with a snap of claim 1, wherein several anti-slip grooves (3) evenly distributed are formed on an outer side of the cover (2).

7. The knob type waterproof optical controller with a snap of claim 4, wherein the sealing gasket (7) is made of waterproof silicone material.
